(19) United States
(12) Patent Application Publication
(10) Pub. No.: US 2009/0200912 A1
(43) Pub. Date: Aug. 13, 2009

(54) Methods for Growing Carbon Nanotubes on Single Crystal Substrates

(75) Inventors: Zhifeng Ren, Newton, MA (US); Guangyong Xiong, Netwon, MA (US); Dezhi Wang, Wellesley, MA (US); Baoqing Zeng, Sichuan (CN)

Correspondence Address: GREENBERG TRAURIG, LLP, ONE INTERNATIONAL PLACE, 20th FL, ATTN: PATENT ADMINISTRATOR, BOSTON, MA, 02110, US

(73) Assignee: The Trustees of Boston College

(21) Appl. No.: 12/090,755

(22) PCT Filed: Oct. 20, 2006
(86) PCT No.: PCT/US2006/041083

§ 371 Date: Sep. 2, 2008

Related U.S. Application Data
(60) Provisional application No. 60/728,510, filed on Oct. 20, 2005.

(51) Int. Cl. H01J 1/00; H01L 21/20

(52) U.S. Cl. 313/311; 438/478; 438/20; 257/E21.09; 977/762

(57) ABSTRACT

Methods for growing carbon nanotubes on single crystal substrates are disclosed. A method of producing a nanostructure material comprises coating a single crystal substrate with a catalyst film to form a catalyst coated substrate; annealing the catalyst film by supplying a first promoter gas to the catalyst coated substrate at a first temperature and a first pressure; and supplying a second promoter gas and a carbon-source gas to the catalyst coated substrate in a substantially water-free atmosphere at a second pressure and a second temperature for a time period to cause growth of nanostructures on the catalyst coated substrate. The nanostructure material is used in various applications.

### GOVERNMENT SUPPORT

The invention was supported, in whole or in part, by grant DE-FG02-00ER45805 from the Department of Energy and by a grant NIRT 0304506 from the National Science Foundation. The U.S. Government has certain rights in the invention.

### FIELD

The embodiments disclosed herein relate to the synthesis of nanostructure materials, and more particularly to methods for growing carbon nanotubes on single crystal substrates.

### BACKGROUND

Since the discovery of carbon nanotubes (CNTs), there has been considerable work on trying to gain controls on the length, diameter, alignment, location, periodicity, number of walls, and chiriality. In one batch of carbon nanotubes it is possible to get a mix of tubules with different diameters and lengths, which are rolled in different ways. This variance makes it impossible to employ these carbon nanotubes in specific applications where their physical properties play an important role. The application of carbon nanotubes (CNTs) to cutting edge research requires close control of CNT growth. Everything from the catalyst used to the growth conditions will affect the quality of the CNTs that are grown. Advanced applications require the growth of CNTs that have a specific geometry, for example, the patterning of the catalyst, the shape of the substrate used, or the height and geometry of the CNTs that are grown. Most applications require the careful selection of the CNT type that is grown: single-walled carbon nanotubes (SWCNTs), or multi-walled carbon nanotubes (MWCNTs). The selection of CNT type has serious ramifications upon the mechanical and electrical properties of the device that is to be created. For example, it has been shown that MWCNTs have higher thermal and chemical stability than SWCNTs. Additionally, the structures that can be created by each type of CNT can also be substantially different. CNTs are actively being investigated for a wide range of applications that include sensors, interconnects, probes, electrical and thermal transport, field emission, and nanoelectronics, each application requiring its own specific design and characteristics.

Though progress has been made during the past years, it is not until recently that very long aligned SWCNTs were grown. These SWCNTs were grown on alumina-coated single crystal silicon substrates by water-assisted chemical vapor deposition (CVD), where water keeps the catalyst active leading to the long length. The long length, also meaning very high purity, is desired for not only applications for high strength but also basic studies such as the effect of impurity on magnetic properties.

Recent field emission devices such as field emission displays and field emission lamps employ CNTs as field emission emitters. The electron emission device is required to allow electron emission at a low electric field and have a high current density and long life. Emitters composed of CNTs have a high electrical conductivity and a high field enhancement factor, thus showing excellent field emission properties. If CNTs provided on an electrode substrate are used as field emission emitters, they can emit electrons even at a low voltage, thereby obtaining an excellent field emission device. A number of methods have been proposed for forming CNT emitters on a substrate. Examples of the methods include a method of growing CNTs on a substrate by chemical vapor deposition (CVD), a method using conductive paste, a method using electroplating, and a method using electrophoresis. There has been difficulty in using CNT growth to obtain emitters due to low productivity. Thus, CNT emitters currently used in field emission displays or field emission lamps are typically manufactured using conductive paste, electroplating, or electrophoresis. Because it is difficult to effectively control a generation density of the carbon nanotubes, the field emission display device has problems in that production yield is low and a large size cannot be realized. CNT emitters manufactured by these methods also show significant variation in electron emission properties. Such variation has a negative effect upon the emission uniformity and lifespan of field emission lamps or field emission displays.

Prior art techniques for growing CNTs that have a specific geometry, for example the patterning of the catalyst, the shape of the substrate used, or the height and geometry of the CNTs grown have been described for applications that include sensors, interconnects, probes, electrical and thermal transport, field emission, and nanoelectronics, and are described in U.S. Pat. No. 7,040,948 entitled “Enhanced field emission from carbon nanotubes mixed with particles,” U.S. Pat. No. 6,798,127 entitled “Enhanced field emission from carbon nanotubes mixed with particles,” U.S. Patent Publication No. 20060198956 entitled “Chemical vapor deposition of long vertically aligned dense carbon nanotube arrays by external control of catalyst composition,” U.S. Patent Publication No. 20060055303 entitled “Method of synthesizing small-diameter carbon nanotubes with electron field emission properties,” U.S. Patent Publication No. 20050090176 entitled “Field emission display and methods of forming a field emission display,” and U.S. Patent Publication No. 20050001528 entitled “Enhanced field emission from carbon nanotubes mixed with particles.”

Thus, there is a need in the art for methods for growing carbon nanotubes on single crystal substrates.

### SUMMARY

Methods for growing carbon nanotubes on single crystal substrates for various applications are disclosed herein.

According to aspects illustrated herein, there is provided a method of producing a nanostructure material comprising coating a single crystal substrate with a catalyst film to form a catalyst coated substrate; annealing the catalyst film by supplying a first promoter gas to the catalyst coated substrate at a first temperature and a first pressure; and supplying a second promoter gas and a carbon-source gas to the catalyst coated substrate in a substantially water-free atmosphere at a second pressure and a second temperature for a time period to cause growth of nanostructures on the catalyst coated substrate.

According to aspects illustrated herein, there is provided a method of producing a field emission emitter comprising coating a single crystal substrate with a catalyst film to form a catalyst coated substrate; annealing the catalyst film by supplying a first promoter gas to the catalyst coated substrate at a first temperature and a first pressure; and supplying a second promoter gas and a carbon-source gas to the catalyst coated substrate in a substantially water-free atmosphere at a second pressure and a second temperature for a time period to cause growth of nanostructures on the catalyst coated substrate.

According to aspects illustrated herein, there is provided a field emission emitter comprising an array of vertically aligned nanostructures grown on a catalyst coated single crystal substrate in a substantially water-free atmosphere, wherein a length of the nanostructures ranges from about 0.05 millimeters to about 2.5 millimeters.

### BRIEF DESCRIPTION OF THE DRAWINGS

The presently disclosed embodiments will be further explained with reference to the attached drawings, wherein like structures are referred to by like numerals throughout the several views. The drawings are not necessarily to scale, the emphasis having instead been generally placed upon illustrating the principles of the presently disclosed embodiments.

FIG. 1A-FIG. 1D show various scanning electron microscope (SEM) images of carbon nanotubes (CNTs) grown on single crystal magnesium oxide (MgO) substrates coated with an iron film. FIG. 1A is a low magnification SEM image showing the length of CNTs and the thickness of magnesium oxide substrate (about 500 μm). FIG. 1B is a medium magnification SEM image of the CNTs of FIG. 1A. FIG. 1C and FIG. 1D show high magnification SEM images of the CNTs of FIG. 1A.

FIG. 2A is a graph showing the effect of growth gas pressure on the length of CNTs synthesized.

FIG. 2B is a graph showing the effect of growth temperature on the length of CNTs synthesized.

FIG. 2C is a graph showing the effect of growth time on the length of CNTs synthesized.

FIG. 3A shows a low magnification transmission electron microscopy (TEM) image of CNTs grown on a MgO substrate.

FIG. 3B shows a high magnification TEM image of CNTs grown on a MgO substrate with an about 0.4 nm catalyst film deposited on the substrate. The majority of CNTs are double wall.

FIG. 3C shows a high magnification TEM image of CNTs grown on a MgO substrate with an about 0.8 nm catalyst film deposited on the substrate. The majority of CNTs are triple wall.

FIG. 3D shows a high magnification TEM image of CNTs grown on a MgO substrate with an about 1.2 nm catalyst film deposited on the substrate. The majority of CNTs are four- and five-wall.

FIG. 4A-FIG. 4D show various scanning electron microscope (SEM) images of carbon nanotubes (CNTs) grown on single crystal Sapphire substrates coated with an iron film. FIG. 4A is a low magnification SEM image showing the length of CNTs (1.8 mm). FIG. 4B is a medium magnification SEM image of the CNTs of FIG. 4A. FIG. 4C and FIG. 4D show high magnification SEM images of the CNTs of FIG. 4A.

FIG. 5A-FIG. 5D show various scanning electron microscope (SEM) images of carbon nanotubes (CNTs) grown on single crystal Silicon substrates coated with a catalyst film of sandwich structure (Fe, 3 nm/ Al, 4 nm/ Fe, 4 nm). FIG. 5A is a low magnification SEM image showing the length of CNTs (800 μm). FIG. 5B is a medium magnification SEM image of the CNTs of FIG. 5A. FIG. 5C is a low magnification SEM images of the CNTs grown on a Silicon substrate coated with catalyst film of stripe pattern. FIG. 5D is a medium magnification SEM image of the CNTs of FIG. 5C.

FIG. 6A-FIG. 6D show various scanning electron microscope (SEM) images of carbon nanotubes (CNTs) grown on single crystal Silicon substrates coated with a catalytic film (3 nm Fe/ 4 nm Al/ 4 nm Fe). FIG. 6A shows a top-view of the CNTs. FIG. 6B shows a top-view of the CNTs when subjected to post-growth thermal annealing conditions. FIG. 6C shows a side-view of the CNTs. FIG. 6D shows a side-view of the CNTs when subjected to post-growth thermal annealing conditions.

FIG. 7A is a field emission property plot showing emission current density (up to 3 mA/cm²) dependence as a function of the macroscopic electric field. The plot shows results for the CNTs of FIG. 6A (represented by the open triangles) and for the CNTs grown and subjected to post-growth thermal annealing conditions of FIG. 6B (represented by the solid circles).

FIG. 7B is a Fowler-Nordheim plot. The plot shows results for the CNTs of FIG. 6A (represented by the open triangles) and for the CNTs grown and subjected to post-growth thermal annealing conditions of FIG. 6B (represented by the solid circles).

FIG. 8 is a field emission property plot showing emission current density (up to 80 mA/cm²) dependence as a function of the macroscopic electric field. The plot shows results for the CNTs of FIG. 6A (represented by the open triangles) and for the CNTs grown and subjected to post-growth thermal annealing conditions of FIG. 6B (represented by the solid circles).

FIG. 9 is a field emission property plot showing emission current density stability as a function of time under continuous electrical field.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The embodiments disclosed herein relate to the synthesis of vertically aligned nanostructure materials, and more particularly to the synthesis of nanostructure materials with controllable parameters for various applications. The following definitions are used to describe the various aspects and characteristics of the presently disclosed embodiments.

As used herein, “nanostructures” and “nanostructure materials” refer to a broad class of materials, with microstructures modulated in zero to three dimensions on length scales less than about 100 nm; materials with atoms arranged in nanosized clusters, which become the constituent grains or building blocks of the material; and any material with at least one dimension in the about 1-100 nm range. Using a variety of synthesis methods, it is possible to produce nanostructured materials in the following forms: thin films, coatings, powders and as a bulk material. In an embodiment, the material comprising the nanostructure is carbon. In an embodiment, the material comprising the nanostructure need not be carbon. In applications where highly symmetric structures are generated, the sizes (largest dimensions) can be as large as tens of microns.

As used herein, “carbon nanotubes”, “CNTs”, and “nanotube” are used interchangeably. These terms primarily refer to cylindrical carbon molecules that have novel properties that make them potentially useful in a wide variety of applications in nanotechnology, electronics, optics, and other fields of materials science. They exhibit extraordinary strength and unique electrical properties, and are efficient conductors of heat.

As used herein, “single-walled carbon nanotubes” (SWCNTs) consist of one graphene sheet rolled into a cylinder. “Multi-walled carbon nanotubes” (MWCNTs) consist of more than one graphene sheet oriented substantially parallel to one another.

As used herein, CNTs are “aligned” wherein the longitudinal axis of individual tubules are oriented in a plane substantially parallel to one another.

As used herein, a “tubule” is an individual CNT.

The CNTs have “proximal” and “distal” ends. The proximal ends of the CNTs are attached to a substrate material (i.e., a magnesium oxide crystal, sapphire crystal or similar material).

As used herein, “linear CNTs” refer to CNTs that do not contain any branches originating from the surface of individual CNT tubules along their linear axes.

As used herein, an “array” refers to a plurality of CNT tubules that are attached to a substrate material.

As used herein, a “single crystal substrate material” can be a substrate that includes, but is not limited to, magnesium oxide, sapphire, silicon, alumina-coated silicon, quartz, alumina-coated quartz, lanthanum aluminate, strontium titanate, and yttrium stabilized zirconia.

As used herein, a “catalytic transition metal” can be any transition metal, transition metal alloy or mixture thereof. Examples of a catalytic transition metal include, but are not limited to, nickel (Ni), silver (Ag), gold (Au), aluminum (Al), platinum (Pt), palladium (Pd), iron (Fe), ruthenium (Ru), osmium (Os), cobalt (Co), rhodium (Rh), iridium (Ir), or combinations thereof.

As used herein, a “catalytic transition metal alloy” can be any transition metal alloy. Preferably, a catalytic transition metal alloy is a homogeneous mixture or solid solution of two or more transition metals. Examples of a catalytic transition metal alloy include, but are not limited to, nickel/gold (Ni/Au) alloy, cobalt/iron (Co/Fe) alloy, iron/cobolt/nickel alloy, and iron/molybdenum alloy.

As used herein, a “promoter gas” can be a substance that is a gaseous compound at the reaction temperatures, and preferably comprises a non-carbon gas such as ammonia, ammonia-nitrogen, hydrogen, thiophene, or mixtures thereof. For the CVD reaction process, hydrogen is preferred for reaction although ammonia, nitrogen, or any combination thereof can be used. The promoter gas can be introduced into the reaction chamber of the reaction apparatus (e.g. the CVD reaction chamber) at any stage of the reaction process. Preferably, the promoter gas is introduced into the reaction chamber either prior to or simultaneously with a carbon source gas. The CNT nanotube nucleation process on the catalyst substrate is catalyzed by the promoter gas and enables every metal catalyst “cap” that is formed within individual tubules to catalyze their efficient and rapid growth.

As used herein, a “carbon source gas” can be saturated, unsaturated linear branched or cyclic hydrocarbons, or mixtures thereof, that are either in the gas or vapor phase at the temperatures at which they are contacted with the catalyst substrate material (reaction temperature). Preferred carbon source gases include methane, propane, acetylene, ethylene, benzene, or mixtures thereof. In an embodiment, the carbon source gas for the synthesis of linear CNTs is ethylene. Ethylene decomposes at a lower temperature then methane and has a much higher decomposition rate, which makes it a good choice to provide an abundant carbon source needed for ultra long CNTs' growth. In an embodiment, the carbon source gas for the synthesis of linear CNTs is acetylene.

As used herein, “nanocrystals,” “nanoparticles” and “nanostructures,” are employed interchangeably.

As used herein, “CVD” refers to chemical vapor deposition. In CVD, gaseous mixtures of chemicals are dissociated at high temperature (for example, CO₂ into C and O₂). This is the “CV” part of CVD. Some of the liberated molecules may then be deposited on a nearby substrate (the “D” in CVD), with the rest pumped away. Examples of CVD methods include but are not limited to, “plasma enhanced chemical vapor deposition” (PECVD), “hot filament chemical vapor deposition” (HFCVD), and “synchrotron radiation chemical vapor deposition” (SRCVD).

As used herein, “water-free” refers to the synthesis of aligned CNTs without the addition of water vapor in the growth atmosphere.

A method of producing nanostructures on single crystal substrates comprises coating a single crystal substrate with a catalyst film to form a catalyst coated substrate; supplying a first promoter gas to the catalyst coated substrate at a first temperature and a first pressure to cause annealing leading to the formation of catalyst particles; and supplying a flow of a second promoter gas and a flow of a carbon-source gas to the catalyst coated substrate in a substantially water-free atmosphere at a second pressure and a second temperature for a period of time to cause growth of nanostructures on the catalyst coated substrate.

In an embodiment, the nanostructures are carbon nanotubes (CNTs). In an embodiment, the single crystal substrate comprises magnesium oxide. In an embodiment, the single crystal substrate comprises sapphire. In an embodiment, the single crystal substrate comprises silicon.

The method may further include a post-growth annealing step. The post-growth annealing step includes annealing in a vacuum for a predetermined amount of time followed by a predetermined time in air.

In an embodiment, CNTs are obtained by placing a catalyst substrate material within a horizontal tube furnace with a quartz tube. In an embodiment, the catalyst substrate comprises a substrate engaged to a catalytic material. In an exemplary method for synthesizing linear aligned carbon nanotubes, a selected thickness of catalytic transition metal is placed on a single crystal substrate to obtain a catalyst substrate material. The thickness of the catalytic transition metal influences the number of walls present in the final carbon nanotubes synthesized. For example, the thickness of the catalytic transition metal can range from about 0.2 nm to about 50 nm. In an embodiment, the thickness ranges from about 0.4 nm to about 20 nm. In an embodiment, the thickness ranges from about 0.8 nm to about 12 nm. Examples of single crystal substrates include, but are not limited to, magnesium oxide, sapphire, silicon, alumina-coated silicon, quartz, alumina-coated quartz, lanthanum aluminate, strontium titanate, and yttrium stabilized zirconia. In an embodiment, the single crystal substrate is magnesium oxide. In an embodiment, the single crystal structure is sapphire. In an embodiment, the single crystal structure is silicon.

The catalyst is coated on the substrate by magnetron sputtering of a catalytic transition metal on the substrate. The catalyst may also be applied to the substrate by electrochemical deposition or other methods known in the art. The substrate comprises a single crystal material. Following placement of the catalyst substrate material in the furnace, CNT growth is initiated on the surface of the catalyst substrate material by standard methods described in the art. (See, for example Z. F. Ren, et al., Science, 282, 1105 (1998); Z. P. Huang, et al., Appl. Phys. A: Mater. Sci. Process, 74, 387 (2002); and Z. F. Ren et al., Appl. Phys. Lett., 75, 1086 (1999), all of which are incorporated herein by reference in their entirety).

Production of aligned linear CNT materials is accomplished by placing a catalyst substrate material into the reaction chamber of a CVD apparatus and exposing the catalyst substrate material to a flow of a promoter gas to cause annealing and the formation of catalyst particles, followed by a flow of a gas mixture containing a carbon source gas and a promoter gas. The gas pressure during the annealing step is an important factor for the subsequent growth of long CNTs. Also, the CNT growth is sensitive to the growth conditions including the flow rate of the feeding gases, the gas pressure and the temperature at the growth zone during growth, and growth time. The CVD chamber temperature, gas pressure and growth time are optimized to control and obtain the desired morphology of carbon nanotubes during their growth.

The growth step may be carried out at different temperatures (from about 740° C. to about 780° C.) and for varying lengths of time (from about 5 minutes to about 60 minutes).

After growth, a scanning electron microscope is used to characterize the length and alignment of the CNTS. A transmission electron microscope is used to characterize the wall numbers, diameter, and graphitization.

CNT tubule diameter, tubule length, wall number, graphitization, and the yield of the CNTs is controlled by varying the thickness of the catalytic transition metal film, the reaction gas pressure, temperature and time during growth.

The length, diameter, number of walls and graphitization of carbon nanotubes can be primarily controlled by choosing proper experimental conditions, for example, catalyst transition metal thickness, pressure during annealing, flow rate of feeding gases, gas pressure and temperature at the growth zone during growth, and growth time.

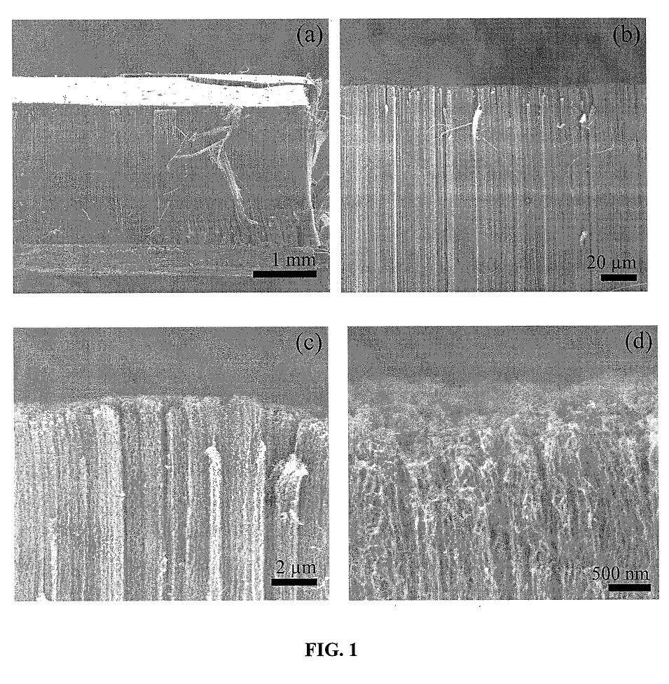

FIG. 1A shows a low magnification scanning electron microscopy (SEM) image of an array of linear aligned CNTs grown on a single crystal MgO substrate coated with an iron catalytic film. An annealing pressure of about 200 Torr followed by growth conditions of flowing hydrogen (H₂) gas (about 100 sccm); flowing ethylene (C₂H₄) gas (about 110 sccm); heating to about 745° C.; a gas pressure of about 760 Torr and a growth time of about 45 minutes resulted in CNTs with a length of about 2.2 mm. FIG. 1B shows a medium magnification SEM image of the array of linear aligned CNTs of FIG. 1A, showing the alignment. By way of example, FIGS. 1A and 1B show that the CNTs are generally aligned linearly and exhibit lengths in a range of about 2.0 mm to about 2.2 mm. FIGS. 1C and 1D are high magnification SEM images of the CNTs of FIG. 1A showing that the tubules have a very small diameter and are curved and may be intertwined with each other. The CNT growth is sensitive to the growth conditions including the flow rate of feeding gases, gas pressure and temperature at the growth zone during growth, and growth time. It is found that a combination of about 100 sccm H₂ with about 110 sccm C₂H₄ is the optimal gas supply, any unilateral adjustment larger than about twenty percent typically results in no CNTs growth.

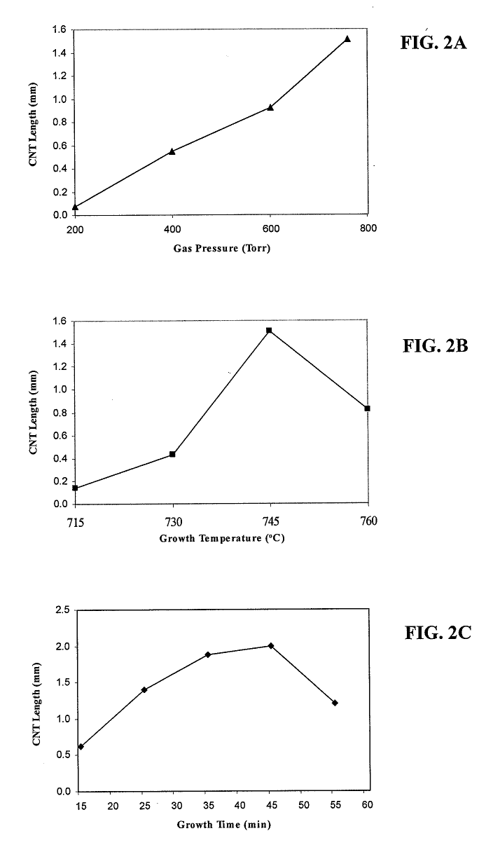

FIG. 2A shows the CNTs length dependence on the gas pressure during growth, with the other growth conditions fixed at about 100 sccm H₂, about 110 sccm C₂H₄, about 745° C., and about 25 minutes. The figure shows that the length of CNTs is related to the carbon supplies since higher pressure provides more carbon atoms. FIG. 2B shows the CNTs length dependence on growth temperature, when the other growth conditions are fixed at about 100 sccm H₂, about 110 sccm C₂H₄, about 760 Torr, and about 25 minutes. When the temperature is too low, there is not enough carbon supply, whereas a too high temperature does not provide enough carbon supply either since the optimal decomposition temperature of C₂H₄ is at about 745° C. FIG. 2C shows the CNTs length dependence on the growth time with the other growth conditions fixed at about 100 sccm H₂, about 110 sccm C₂H₄, about 745° C., and about 760 Torr. Initially, the growth of CNTs is much faster than the oxidation resulting in quick growth. During growth, the catalyst is being consumed. After the catalyst is completely consumed at about 45 minutes, the growth stops and only oxidation continues. As such, the CNTs become shorter with time longer than about 45 minutes.

In an embodiment, the growth conditions for obtaining long, linear aligned CNTs grown on single crystal substrates coated with a catalyst transition metal is feeding gases of about 100 sccm for H₂, about 110 sccm for C₂H₄; a growth temperature of about 745° C.; a growth pressure of about 760 Torr, and a growth time of about 45 minutes.

For growth of long, linear aligned CNTs grown on single crystal substrates coated with a catalyst transition metal, it is not necessary to have water vapor present in the promoter gas. This is an important point since previously water vapor was used to fabricate long SWCNTs. Here, it is disclosed that long MWCNTs including two-walls (DWCNTs) can be fabricated without the use of water.

As known, the thickness of the catalytic film influences the final diameter of CNTs. In an embodiment, long CNTs were grown to a desired diameter by varying the catalyst transition metal film thickness. As such, catalyst transition metal film thickness of about 0.4 nm, about 0.8 nm, and about 1.2 nm were used in order to develop a relationship between the final diameter of long CNTs grown in accordance with aspects of the method illustrated herein and thickness of the catalyst transition metal. After growth, the microstructures of the CNTs were studied using high resolution TEM. As expected, it was found that the thickness of the catalyst film affects the outer diameter, however, surprisingly the catalyst film thickness also may control the number of walls (SWCNTs versus DWCNTs versus MWCNTs).

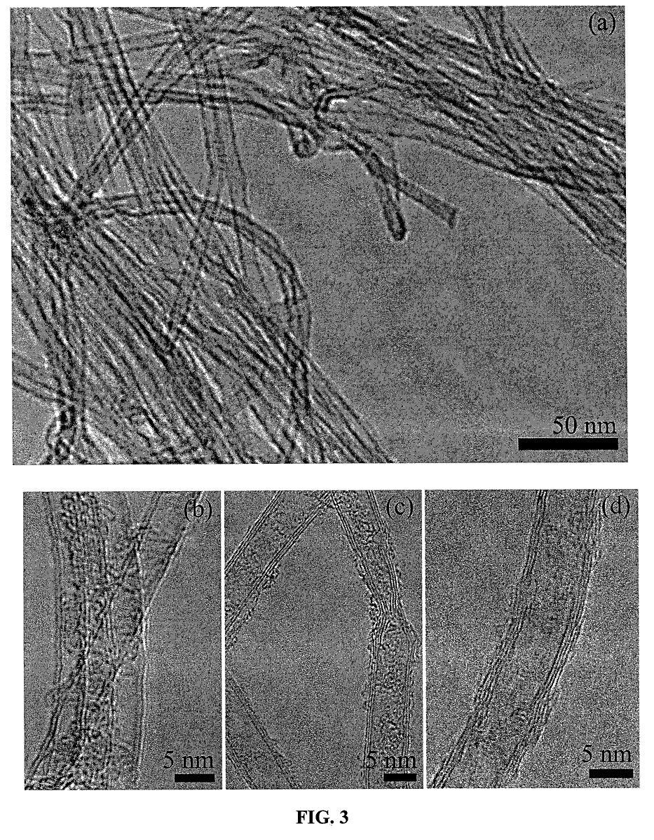

FIG. 3A shows CNTs free of catalyst particles, consistent with previous reports. For about a 0.4 nm catalyst film, the majority of CNTs are DWCNTs, see FIG. 3B. For about a 0.8 nm catalyst film, the CNTs are mostly three-wall CNTs as shown in FIG. 3C with a small quantity of four-wall CNTs. For about a 1.2 nm catalyst film, the majority of the CNTs are four- and five-wall as shown in FIG. 3D.

Besides the effect of catalyst film thickness on wall numbers and inner and outer diameters, the length of CNTs is also closely related to the thickness of the catalyst film. The longest CNTs grown on about a 0.4 nm film substrate is about 80 μm, while the longest CNTs grown on about a 0.8 nm film substrate is about 1.1 mm, and the longest CNTs grown on about a 1.2 nm film substrate is about 2.2 mm. With much thicker catalyst film, the length starts to decrease. As such, varying the thickness of the catalyst film allows for the optimization of the carbon nanotubes grown in accordance with aspects of the method illustrated herein.

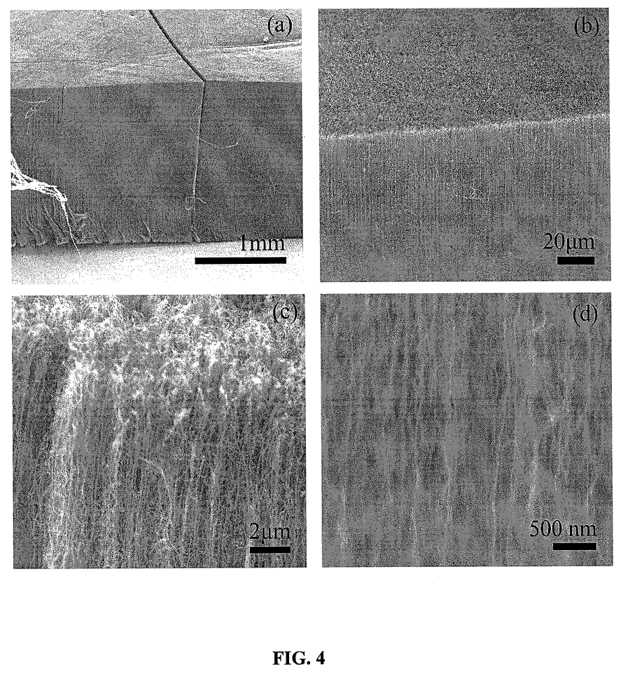

FIG. 4A shows a low magnification scanning electron microscopy (SEM) image of an array of linear aligned CNTs grown on a single crystal sapphire substrate coated with an iron catalytic film. An annealing pressure of about 200 Torr followed by growth conditions of flowing hydrogen (H₂) gas (about 100 sccm); flowing ethylene (C₂H₄) gas (about 110 sccm); heating to about 745° C.; a gas pressure of about 760 Torr and a growth time of about 45 minutes resulted in CNTs with a length of about 1.8 mm. FIG. 4B shows a medium magnification SEM image of the array of linear aligned CNTs of FIG. 4A, showing the alignment. By way of example, FIGS. 4A and 4B show that the CNTs are generally aligned linearly and exhibit lengths in a range of about 1.5 mm to about 1.8 mm. FIGS. 4C and 4D are high magnification SEM images of the CNTs of FIG. 4A showing that the tubules have a very small diameter and are curved and may be intertwined with each other. The CNT growth is sensitive to the growth conditions including the flow rate of feeding gases, gas pressure and temperature at the growth zone during growth, and growth time. It is found that a combination of about 100 sccm H₂ with about 110 sccm C₂H₄ is the optimal gas supply, any unilateral adjustment larger than about twenty percent typically results in no CNTs growth.

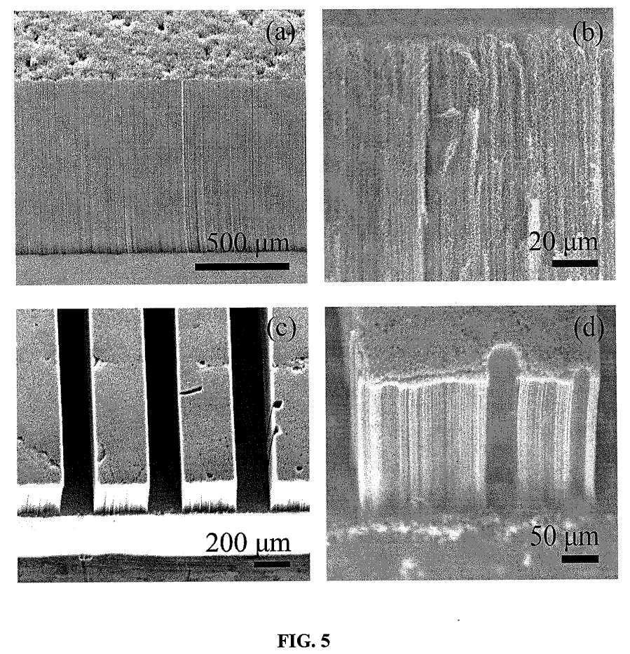

FIG. 5A shows a low magnification scanning electron microscopy (SEM) image of an array of linear aligned CNTs grown on a single crystal silicon substrate coated with a catalyst film of sandwich structure (Fe, 3 nm/ Al, 4 nm/ Fe, 4 nm respectively). An annealing pressure of about 200 Torr followed by growth conditions of flowing hydrogen (H₂) gas (about 100 sccm); flowing ethylene (C₂H₄) gas (about 110 sccm); heating to about 745° C.; a gas pressure of about 760 Torr and a growth time of about 30 minutes resulted in CNTs with a length of about 900 μm. FIG. 5B shows a medium magnification SEM image of the array of linear aligned CNTs of FIG. 5A, showing the alignment. By way of example, FIGS. 5A and 5B show that the CNTs are generally aligned linearly and exhibit lengths in a range of about 750 to about 900 μm. FIG. 5C shows a low magnification scanning electron microscopy (SEM) image of stripe-pattern arrays of linear aligned CNTs grown on a single crystal Silicon substrate coated with a stripe-pattern catalyst film of sandwich structure (Fe, 3 nm/ Al, 4 nm/ Fe, 4 nm respectively). An annealing pressure of about 200 Torr followed by growth conditions of flowing hydrogen (H₂) gas (about 100 sccm); flowing ethylene (C₂H₄) gas (about 110 sccm); heating to about 745° C.; a gas pressure of about 760 Torr and a growth time of about 25 minutes resulted in CNTs with a length of about 200 μm. FIG. 5D shows a medium magnification SEM image of the arrays of linear aligned CNTs of FIG. 5C, showing the alignment. FIGS. 5C and 5D show that aligned CNT arrays with specific patterns can be achieved by selective deposition of catalyst film.

The embodiments disclosed herein relate to the synthesis of vertically aligned nanostructures, and more particularly to the synthesis of nanostructures on single crystal substrates and their potential applications. The nanostructures of the presently disclosed embodiments can be used in various applications, including, but not limited to, field emission devices, nanosize devices in which thermal management and the thermal conduction of nanometer materials plays a fundamentally critical role that controls the performance and stability of nano/micro devices, analog and radio frequency applications in which the high capacitance of the nanostructures allows charge storage, electronic interconnect devices, and as reinforcement fillers for ceramics, polymers and similar structures.

CNTs have high electrical conductivity, heat conductivity, and mechanical properties. CNTs are excellent field emitters, given their high electrical conductivity. CNTs can carry a high current density, and the current is extremely stable. An application of this behavior is in field-emission flat-panel displays. Instead of a single electron gun, as in a traditional cathode ray tube display, in CNT-based displays there is a separate electron gun (or even many of them) for each individual pixel in the display. Their high current density, low turn-on and operating voltages, and steady, long-lived behavior make CNTs attractive field emitters. Other applications utilizing the field-emission characteristics of CNTs include general types of low-voltage cold-cathode lighting sources, lightning arrestors, and electron microscope sources.

Reducing the size of electronic devices and integrated micro/nano-electro-mechanical systems (MEMS and NEMS) allows CNTs to be used for thermal management. Thermal management in nanosize devices becomes increasingly important as the size of the device reduces. The thermal conduction of nanoscale materials controls the performance and stability of nano/micro devices. CNTs can be used for MEMS/NEMS applications due to their properties, such as high strength, light weight, special electronic structures, and high stability, make CNTs an ideal material for a wide range of applications. The thermal properties of CNTs are directly related to their unique structure and small size. Because of these properties, CNTs are an ideal material for the study of low-dimensional phonon physics, and for thermal management, both on the macro- and the micro-scale.

The range of applications employing CNTs for energy storage and conversion include fuel cells, batteries, supercapacitors, solar cells, and thermionic power devices. In fuel cells, CNTs can be utilized for hydrogen storage and in developing new composite materials for proton exchange membranes. The large surface area of the CNTs, due to their small diameter, allows them to store charge. CNTs can be used for lithium storage in lithium-ion batteries and used in novel carbon-carbon battery types. CNTs can be used as electrodes in electrochemical double layer capacitors for supercapacitors. Nanotube-based composite materials can be used in solar cells. Devices can exploit thermionic emission of carbon nanotubes for producing electric energy from residual heat. The use of nanotubes in energy storage and conversion applications affects several major industries.

In the application of semiconductor nanostructures to electronic devices, interconnections between individual nanostructures are important for transmitting and processing signals. With traditional wiring technology, it is difficult to fabricate the connectors between ultra-fine and dense nanostructures. CNTs can be used for wiring and connecting nano-scale devices because of their unique mechanical and electrical properties.

CNTs are strong and resilient structures that can be bent and stretched into shapes without catastrophic structural failure in the nanotube. CNTs have high Young's modulus and tensile strength. This mechanical strength allows CNTs to be used as reinforcing materials. CNTs could reinforce allowing very strong and light materials to be produced. CNTs can absorb the load which is applied to nanocomposite material.

Carbon nanotubes (CNTs), due to their high aspect ratio, chemical inertness and electrical conductivity, are useful as a cold-cathode material. CNTs are suited for vacuum microelectronic devices, such as large area field-emission flat panel displays, vacuum microwave tubes, x-ray sources, and similar devices known to those skilled in the art. To enhance the field emission properties of CNTs, some effective methods have been experimented, such as plasma treatment after growth, controlling the site densities of CNTs during growth to decrease the electrostatic screening effect, depositing alkali metals to reduce the work function, laser treatment, and annealing in oxygen or ozone to open the end of nanotubes.

In an embodiment, the nanostructure materials of the presently disclosed embodiments are grown by thermal chemical vapor deposition methods disclosed herein followed by a post-growth thermal annealing process. The post-growth thermal annealing process results in an improvement in the field emission current density, which may be attributed to the substantial increase of the emitting area of carbon nanotubes after the post-growth annealing step. The increase in the field emission current density is important for applications of using carbon nanotubes as high current electron sources, microwave devices, flat panel displays, and similar devices known to those skilled in the art.

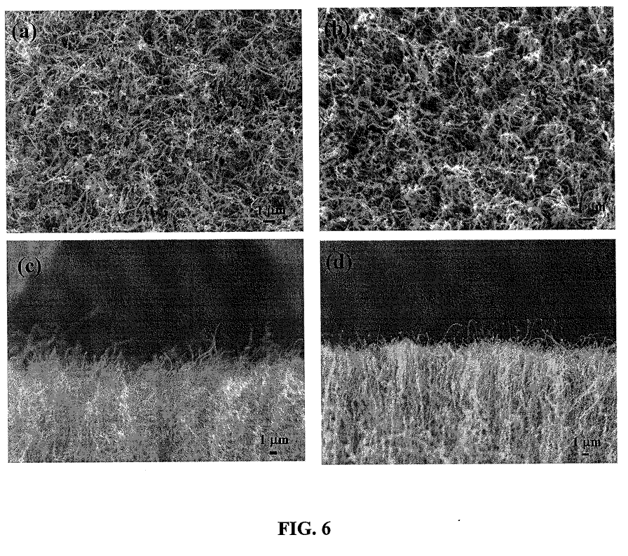

FIG. 6A-FIG. 6D show scanning electron microscopy images of an array of linear aligned CNTs of about 10-20 nm in diameter and about 25-200 μm in length grown on a single crystal silicon substrate coated with an about 11 nm thick catalytic film (3 nm Fe/ 4 nm Al/ 4 nm Fe). An annealing pressure of about 200 Torr followed by growth conditions of flowing hydrogen H₂ gas (about 100 sccm, 99.999% purity) for 10 minutes to form the required catalyst particles and to enhance the catalyst activity; flowing ethylene (C₂H₄) gas (about 100 sccm, 99.6% purity); heating to about 740-780° C.; a gas pressure was adjusted to one atmosphere by controlling the exhaust valve for CNTs growth and a growth time of about 5 to about 60 minutes depending on the length requirement. After growth, the sample was cut into two parts, one, designated as as-grown, was used for field emission measurement directly, and another was annealed in vacuum at about 850° C. for about 1 hour plus about 465° C. for 2 hours in air. Without being limited to any particular theory, the about 850° C. annealing in a vacuum may improve the bonding of CNTs with the single crystal substrate, and graphitization of the CNTs, whereas the annealing in air may remove the amorphous carbon and purify the CNTs.

FIG. 6A shows a top view of the morphologies of the as-grown CNT films. FIG. 6B shows a top view of the morphologies of the annealed CNT films. From the SEM images, it is determined that the nanotubes are about 60 μm long and 30 nm in diameter. After the annealing step, the density of the CNTs seems to be decreased. Moreover, some intertwisted carbon nanotubes on the surface of the as-grown sample (FIG. 6C) has been separated by annealing (FIG. 6D).

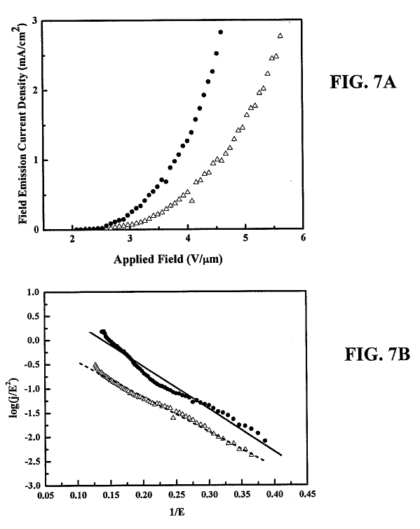

The measured emission current density as a function of the macroscopic electric field is shown in FIG. 7. A turn-on electric field of about 2.6 V/μm was obtained at an emission current density of about 0.01 mA/cm² for the as-grown samples (represented by the open triangles), and about 2.5 V/μm for the annealed samples (represented by the solid circles). An emission current density of about 1 mA/cm² was obtained at about 4.6 V/μm for the as-grown samples, which is higher than that of the annealed ones (about 3.8 V/μm) (FIG. 7A). The Fowler-Nordheim plots for the measured samples are shown in FIG. 7B (The symbols represent the same as in FIG. 7A). The measured data fits into a linear relationship, which confirmed the field emission nature of the CNTs. From the intercepts and slopes of the Fowler-Nordheim plots assuming a work function of 5 eV, it was estimated that the total real emitting areas are of about 1.4×10⁻¹² cm² and about 1.2×10⁻¹⁰ cm² for the as-grown and annealed samples, respectively. The larger emitting area for the annealed sample is most likely the result of oxidation that removes some amorphous carbon and exposes carbon nanotubes.

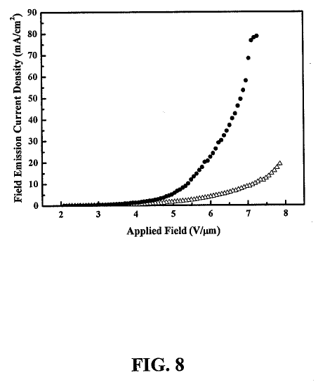

The highest obtained emission current density (about 79 mA/cm²) for the annealed samples is much higher than that (about 19 mA/cm²) of the as-grown samples, as shown in FIG. 8. Annealing is demonstrated to be an effective way to improve the emission current density. Such high current density is a big step towards the application of using carbon nanotubes as high current sources in microwave devices. It has been found that an increase in the current density is dependent on the carbon nanotube length, thus achieving long carbon nanotubes is desirable for many applications.

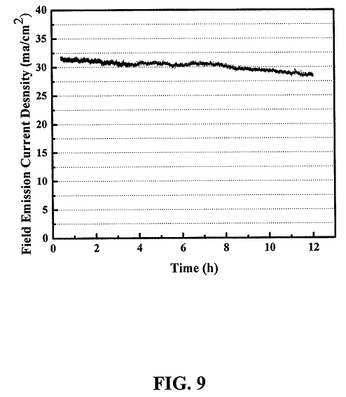

For any practical application, stability of emission current density is essential. FIG. 9 shows the results of a stability test. A starting current density of about 31.6 mA/cm² at about 1×10⁻⁶ Torr was used. After about 12 hours of continuous dc emission, the current density dropped from about 31.6 to about 28.4 mA/cm², about a 10% degradation.

A method of producing a nanostructure material comprises coating a single crystal substrate with a catalyst film to form a catalyst coated substrate; annealing the catalyst film by supplying a first promoter gas to the catalyst coated substrate at a first temperature and a first pressure; and supplying a second promoter gas and a carbon-source gas to the catalyst coated substrate in a substantially water-free atmosphere at a second pressure and a second temperature for a time period to cause growth of nanostructures on the catalyst coated substrate.

A method of producing a field emission emitter comprises coating a single crystal substrate with a catalyst film to form a catalyst coated substrate; annealing the catalyst film by supplying a first promoter gas to the catalyst coated substrate at a first temperature and a first pressure; and supplying a second promoter gas and a carbon-source gas to the catalyst coated substrate in a substantially water-free atmosphere at a second pressure and a second temperature for a time period to cause growth of nanostructures on the catalyst coated substrate.

The growth of CNTs oil a magnesium oxide substrate is disclosed. Single crystal magnesium oxide (MgO) substrates with orientations of [100], [110], and [111] are cleaned in alcohol by ultra-sonication, then loaded into a sputtering chamber for catalyst film deposition in order to form a catalyst-coated MgO substrate. A base pressure of about 3×10⁻⁶ Torr is obtained before argon gas is introduced for sputtering at about 3 mTorr. The sputtering process takes about a few seconds to about 20 minutes to achieve a catalyst film thickness of about 0.2 nm to about 50 nm depending on time. Once the catalyst substrate is formed, the catalyst-coated MgO substrate is loaded into a small quartz boat and pushed to the center of a furnace, then the furnace is pumped down to about 1 mTorr by a rotary pump, followed by heating to about 745° C. within about 10 minutes, then supplying flowing H₂ gas (100 standard cubic centimeter per minute (sccm)) to reach a pressure of about 200 Torr and kept at the temperature and pressure for 10 minutes to anneal the catalyst film to form catalyst particles on the substrate. After the annealing step, the furnace is pumped down to about 1 mTorr, followed by introducing flowing gases of H₂ (about 100 sccm) and C₂H₄ (about 110 sccm) with the pump turned off. When the pressure reaches about one atmosphere (about 760 Torr), a valve is opened to atmosphere to maintain the pressure inside the furnace at about 760 Torr.

The growth of CNTs on a sapphire substrate is disclosed. Single crystal sapphire substrates are loaded into a sputtering chamber for iron catalyst film deposition in order to form an iron catalyst-coated sapphire substrate. The sputtering process takes about a few seconds to about 20 minutes to achieve a catalyst film thickness of about 0.2 nm to about 50 nm depending on time. Once the catalyst substrate is formed, the catalyst-coated sapphire substrate is loaded into a small quartz boat and pushed to the center of a furnace. An annealing pressure of about 200 Torr followed by growth conditions of flowing hydrogen (H₂) gas (about 100 sccm); flowing ethylene (C₂H₄) gas (about 110 sccm); heating to about 745° C.; a gas pressure of about 760 Torr and a growth time of about 45 minutes resulted in CNTs with a length of about 1.8 mm.

The growth of CNTs on a silicon substrate is disclosed. A single crystal Silicon substrate is coated with a catalyst film of sandwich structure (Fe, 3 nm/ Al, 4 nm/ Fe, 4 nm respectively). An annealing pressure of about 200 Torr followed by growth conditions of flowing hydrogen (H₂) gas (about 100 sccm); flowing ethylene (C₂H₄) gas (about 110 sccm); heating to about 745° C.; a gas pressure of about 760 Torr and a growth time of about 30 minutes results in CNTs with a length of about 750 to about 900 μm.

The growth of CNTs on a silicon substrate is disclosed. A single crystal silicon wafer (As-doped n-type, resistance 0.001 Ωcm, [100] orientation, Recticon Enterprises, Inc.) is coated with about a 11-nm thick film (3 nm Fe/ 4 nm Al/ 4 nm Fe) by RF magnetron sputtering. CNTs growth is carried out in a tube furnace by a thermal chemical vapor deposition technique. The catalyst layer is first heat-treated at about 740-780° C. in about 200 Torr of flowing H₂ (about 100 sccm, 99.999% purity) for about 10 minutes to form the required catalyst particles and to enhance the catalyst activity, followed by flowing C₂H₄ (about 100 sccm, 99.6%) while keeping the flowing H₂, the pressure is adjusted to one atmosphere by controlling the exhaust valve for CNTs growth for about 5-60 minutes depending on the length requirement.

After growth, the sample may be annealed in a vacuum at about 850° C. for 1 hour plus about 465° C. for about 2 hours in air to determine the effect of annealing after growth on the field emission properties of the CNTs. The field emission measurements are carried out in a diode configuration. The anode is a molybdenum disk with a diameter of 3 mm, and the gap between the sample surface and the anode is about 270 μm. The vacuum level is kept at about 1×10⁻⁶ Torr during the measurements. Before the emission current measurement, an electrical conditioning is conducted to get stable field emission.

All patents, patent applications, and published references cited herein are hereby incorporated by reference in their entirety. It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A method of producing a nanostructure material comprising:
coating a single crystal substrate with a catalyst film to form a catalyst coated substrate;
annealing the catalyst film by supplying a first promoter gas to the catalyst coated substrate at a first temperature and a first pressure; and
supplying a second promoter gas and a carbon-source gas to the catalyst coated substrate in a substantially water-free atmosphere at a second pressure and a second temperature for a time period to cause growth of nanostructures on the catalyst coated substrate.

2. The method of claim 1 wherein the single crystal substrate is magnesium oxide.

3. The method of claim 1 wherein the single crystal substrate is sapphire.

4. The method of claim 1 wherein the catalyst film is iron.

5. The method of claim 1 wherein the catalyst film is aluminum.

6. The method of claim 1 wherein the first promoter gas and the second promoter gas are hydrogen gas.

7. The method of claim 1 wherein the carbon-source gas is ethylene.

8. The method of claim 1 further comprising annealing in a vacuum for a predetermined amount of time followed by a predetermined time in air.

9. The method of claim 1 wherein the single crystal substrate is coated with the catalyst film at a pre-determined thickness.

10. The method of claim 9 wherein the pre-determined thickness of the catalyst film is selected to provide a desired number of walls for the nanostructures grown.

11. The method of claim 1 wherein the length of the nanostructures grown range from about 0.05 millimeters to about 2.5 millimeters.

12. The method of claim 1 wherein the nanostructure material is used in a field emission device.

13. The method of claim 1 wherein the nanostructure material is used for thermal management.

14. A method of producing a field emission emitter comprising:
coating a single crystal substrate with a catalyst film to form a catalyst coated substrate;
annealing the catalyst film by supplying a first promoter gas to the catalyst coated substrate at a first temperature and a first pressure; and
supplying a second promoter gas and a carbon-source gas to the catalyst coated substrate in a substantially water-free atmosphere at a second pressure and a second temperature for a time period to cause growth of nanostructures on the catalyst coated substrate.

15. The method of claim 14 further comprising a post-growth annealing process.

16. The method of claim 14 further comprising annealing in a vacuum for a predetermined amount of time followed by a predetermined time in air.

17. The method of claim 15 wherein the post-growth annealing process results in the field emission emitter having a higher emission current density, a lower electrical field, and a higher emitter area.

18. A field emission emitter comprising an array of vertically aligned nanostructures grown on a catalyst coated single crystal substrate in a substantially water-free atmosphere, wherein a length of the nanostructures ranges from about 0.05 millimeters to about 2.5 millimeters.

19. The field emission emitter of claim 18 wherein the nanostructures are carbon nanotubes.

20. The field emission emitter of claim 18 wherein the nanostructures are approximately equal in length.
